(19) United States
(12) Patent Application Publication
(10) Pub. No.: US 2023/0212752 A1
(43) Pub. Date: Jul. 6, 2023

(54) SUBSTRATE SUPPORTS, SEMICONDUCTOR PROCESSING SYSTEMS HAVING SUBSTRATE SUPPORTS, AND METHODS OF MAKING SUBSTRATE SUPPORTS FOR SEMICONDUCTOR PROCESSING SYSTEMS

(71) Applicant: ASM IP Holding B.V., Almere (NL)

(72) Inventors: Zhengyan Zhou, Sanya (CN); Hong Gao, San Jose, CA (US)

(21) Appl. No.: 18/147,106

(22) Filed: Dec. 28, 2022

Related U.S. Application Data
(60) Provisional application No. 63/295,604, filed on Dec. 31, 2021.

(51) Int. Cl. C23C 16/46; H01L 21/687; H05B 3/28

(52) U.S. Cl. CPC C23C 16/46; H01L 21/68785; H05B 3/283; H01J 37/32357

(57) ABSTRACT

A substrate support includes a heater body, a heater element, and a heater terminal. The heater body is formed from a ceramic material and has upper and lower surfaces separated by a thickness. The heater element is arranged between the upper and lower surfaces and is embedded within the ceramic material forming the heater body. The heater terminal is arranged between the upper and lower surfaces, is electrically connected to the heater element, and has an electrode surface and a rounded surface. The electrode surface opposes the lower surface to flow an electric current to the heater element. The rounded surface opposes the upper surface and is embedded within the ceramic material to limit stress within the ceramic material during heating of a substrate seated on the upper surface of the heater body. Semiconductor processing systems and methods of making substrate supports for semiconductor processing systems are also described.

### CROSS-REFERENCE TO RELATED APPLICATIONS

This application claims priority to U.S. Provisional Patent Application Ser. No. 63/295,604 filed Dec. 31, 2021 titled SUBSTRATE SUPPORTS, SEMICONDUCTOR PROCESSING SYSTEMS HAVING SUBSTRATE SUPPORTS, AND METHODS OF MAKING SUBSTRATE SUPPORTS FOR SEMICONDUCTOR PROCESSING SYSTEMS, the disclosure of which is hereby incorporated by reference in its entirety.

### FIELD OF INVENTION

The present disclosure generally relates to fabricating semiconductor devices. More particularly, the present disclosure relates to supporting substrates within semiconductor processing systems during the fabrication of semiconductor devices.

### BACKGROUND OF THE DISCLOSURE

Semiconductor devices are commonly fabricated using semiconductor processing systems adapted to perform various processing operations including patterning, etching, and material layer deposition. Etching and material layer deposition, for example, are generally accomplished by supporting a substrate on a substrate support, heating the substrate to a desired material layer deposition temperature, and flowing a material layer precursor through the process chamber and across the substrate. As the material layer precursor flows through the process chamber and across the substrate a chemical reaction generally occurs. The chemical reaction generally causes a material layer to deposit onto the substrate, typically at a rate corresponding to the temperature at which the substrate has been heated. Material layer deposition onto the substrate may be accomplished using a chemical vapor deposition (CVD) technique such as epitaxy, an atomic layer deposition (ALD) technique, or using a plasma enhanced CVD or ALD technique.

In some film deposition techniques, substrate heating may be accomplished using a ceramic heater. Such ceramic heaters may include a heating element, such as electrical heating element or fluid circuit, arranged within the interior of the ceramic heater and in thermal communication with the bulk material forming the ceramic heater. The heating element in generally arranged to communicate heat to one or more substrate supported on the ceramic heating element through the ceramic material forming the ceramic heater, the ceramic material relaying heat generated by the heating element to heat the substrate to the desired deposition temperature. While generally acceptable for their intended purpose, the ceramic material forming the ceramic heater may, in some deposition techniques, be subject to cracking.

Various countermeasures exist to limit cracking in the ceramic material employed in ceramic heaters. For example, the desired deposition temperature may be restricted to temperatures below those at which cracking is exhibited by the bulk material forming the ceramic heater. Alternatively (or additionally), the rate at which the substrate is heated may be restricted to ramp rates below those at which cracking is exhibited by the bulk material forming the ceramic heater. And composition of the ceramic material forming the heater itself may be changed to a composition exhibiting resistance to cracking at the material layer deposition temperature employed in the material layer deposition process, potentially improving reliability of the semiconductor processing system employing the ceramic heater.

While generally acceptable for its intended purpose, limiting material deposition temperature and/or thermal slew can limit throughput of the semiconductor processing system employing the ceramic heater, and changes to the bulk material forming the ceramic material can require time consuming qualification and testing to limit risk that that the new material does not adversely influence properties of material layers deposited onto substrates.

Such methods and systems have generally been considered suitable for their intended purpose. However, there remains a need in the art for improved substrate supports, semiconductor processing systems, and methods of making substrate supports for semiconductor processing systems. The present disclosure provides a solution to this need.

### SUMMARY OF THE DISCLOSURE

A substrate support is provided. The substrate support includes a heater body, a heater element, and a heater terminal. The heater body is formed from a ceramic material and has upper and lower surfaces separated by a thickness of the heater body. The heater element is arranged between the upper and lower surfaces of the heater body, and is embedded within the ceramic material forming the heater body. The heater terminal is arranged between the upper and lower surfaces of the heater body, is electrically connected to the heater element, and has an electrode surface and a rounded surface. The electrode surface of the heater terminal opposes the lower surface of the heater body to flow an electric current to the heater element. The rounded surface of the heater terminal opposes the upper surface of the heater body and is embedded within the ceramic material to limit stress within the ceramic material during heating of a substrate seated on the upper surface of the heater body.

In addition to one or more of the features described above, or as an alternative, further examples of the substrate support may include that the rounded surface of the terminal spans the electrode surface of the heater terminal, and that the rounded surface has a semicircular profile with a convex shape relative to the upper surface of the heater body.

In addition to one or more of the features described above, or as an alternative, further examples of the substrate support may include that the rounded surface has an apex, and that the heater element is electrically connected to the heater terminal between the apex and the electrode surface of the heater terminal.

In addition to one or more of the features described above, or as an alternative, further examples of the substrate support may include that the heater terminal includes molybdenum or a molybdenum-containing alloy.

In addition to one or more of the features described above, or as an alternative, further examples of the substrate support may include that the rounded surface has a rounded surface roughness, that the electrode surface has an electrode surface roughness, and that the rounded surface roughness is less than the electrode surface roughness.

In addition to one or more of the features described above, or as an alternative, further examples of the substrate support may include that the rounded surface of the heater terminal has a rounded surface roughness that is between about 1000 angstroms and about 100 angstroms, or is between about 500 angstroms and about 100 angstroms, or is between about 200 angstroms and about 100 angstroms.

In addition to one or more of the features described above, or as an alternative, further examples of the substrate support may include that the rounded surface of the heater terminal defines (a) a semicircular profile, (b) a parabolic profile, or a (c) a circular profile.

In addition to one or more of the features described above, or as an alternative, further examples of the substrate support may include that the ceramic material extends contiguously between the upper surface and the lower surface of the heater body.

In addition to one or more of the features described above, or as an alternative, further examples of the substrate support may include that the ceramic material extends contiguously between laterally opposite sides of the heater body.

In addition to one or more of the features described above, or as an alternative, further examples of the substrate support include that the ceramic material forming the heater body includes alumina, aluminum nitride, silicon carbide, yttrium oxide, or a ceramic composite having two or more ceramic compositions.

In addition to one or more of the features described above, or as an alternative, further examples of the substrate support may include that the lower surface of the heater body defines a recess, and wherein the electrode surface bounds the recess.

In addition to one or more of the features described above, or as an alternative, further examples of the substrate support may include that the electrode surface of the heater terminal is at least partially embedded within the ceramic material forming the heater body.

In addition to one or more of the features described above, or as an alternative, further examples of the substrate support may include that the electrode surface of the heater terminal is at least partially exposed the environment external to the heater body.

In addition to one or more of the features described above, or as an alternative, further examples of the substrate support may include that the upper surface and the lower surface of the heater body define a (a) disc-like shape, (b), a polygonal shape, (c) a square shape, or (d) a rectangular shape.

In addition to one or more of the features described above, or as an alternative, further examples of the substrate support may include that the rounded surface of the heater terminal joins the electrode surface of the heater terminal at an acute angle.

In addition to one or more of the features described above, or as an alternative, further examples of the substrate support may include that the rounded surface of the heater terminal joins the electrode surface of the heater terminal at a filleted surface.

In addition to one or more of the features described above, or as an alternative, further examples of the substrate support may include that the rounded surface is a first rounded surface, that the heater terminal has a second rounded surface, and that the first rounded surface separates the second rounded surface from the upper surface of the heater body.

In addition to one or more of the features described above, or as an alternative, further examples of the substrate support may include that the rounded surface and electrode surface define a contiguous circular profile between the upper surface and the lower surface of the heater body.

In addition to one or more of the features described above, or as an alternative, further examples of the substrate support may include that the heater element is a first heater element, that the substrate support includes a second heater element embedded within the ceramic material between the first heater element and the lower surface of the heater body, and that the heater terminal defines a circular profile within the thickness of the heater body.

A semiconductor processing system is provided. The semiconductor processing system includes a gate valve, a substrate transfer robot, a chamber body, and a substrate support as described above. The substrate transfer robot is supported for movement relative to the gate valve. The chamber body is connected to the gate valve. The substrate support is arranged within an interior of the chamber body. The ceramic material forming the heater body includes aluminum nitride, the upper surface and the lower surface of the heater define a disc-like shape, and the rounded surface of the heater terminal defines a semicircular profile with a convex shape relative to the upper surface of the heater body.

A method of making a substrate support for a semiconductor processing system includes defining a heater terminal with a rounded surface and an electrode surface, electrically connecting a heater element to the heater terminal, and embedding the heater element and the heater terminal within a ceramic powder. The ceramic powder is sintered to form a sintered powder compact and the sintered powder compact to define a heater body formed from a ceramic material and having an upper surface and a lower surface. The positioning of the heater element and the heater within the ceramic powder is such that the heater element and the heater terminal are arranged between the upper surface and the lower surface of the heater body, the electrode surface opposes the lower surface of the heater body to flow an electric current to the heater element, and the rounded surface opposes the upper surface of the heater body and is embedded within the ceramic material to limit stress within the ceramic material during heating of a substrate seated on the upper surface of the heater body.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a substrate support in accordance with the present disclosure, schematically showing a substrate seated on the substrate support during deposition of a material layer onto the substrate;

FIG. 2 is a plan view of the substrate support of FIG. 1, schematically showing a heater element embedded within a heater body of the substrate support and electrically connected to first and second heater terminals to heat the substrate seated on the substrate support;

FIG. 3 is a cross-sectional view of the substrate support of FIG. 1 according to a first example of the present disclosure, schematically showing the heater element embedded within a ceramic material and connected to first and second heater terminals having rounded surfaces;

FIG. 4 is a cross-sectional view of a portion of the substrate support of FIG. 1 according to the first example of the present disclosure, schematically showing heater terminal defining a semicircular profile embedded in the ceramic material forming the heater body;

FIG. 5 is a cross-sectional view of a portion of the substrate support of FIG. 1 according to another example of the present disclosure, schematically showing a heater terminal having a filleted surface coupling the rounded surface to the electrode surface;

FIG. 6 is a cross-sectional view of a portion of the substrate support of FIG. 1 according to a further example of the present disclosure, schematically showing a heater terminal with a rounded surface defining a parabolic profile between the upper and lower surfaces of the heater body;

FIG. 7 is a cross-sectional view of a portion of the substrate support of FIG. 1 according to another example of the present disclosure, showing a first heater terminal having a rounded surface with a parabolic profile;

FIG. 8 is a cross-sectional view of a portion of the substrate support of FIG. 1 according to a further example of the present disclosure, showing a heater terminal having a rounded surface defining a circular profile;

FIG. 9 is a cross-sectional view of a portion of the substrate support of FIG. 1 according to another example of the present disclosure, showing a first heater terminal having a polished rounded surface embedded within the ceramic material forming the heater body; and

FIGS. 10-12 is a block diagram of a method of making a substrate support for a semiconductor processing system; showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

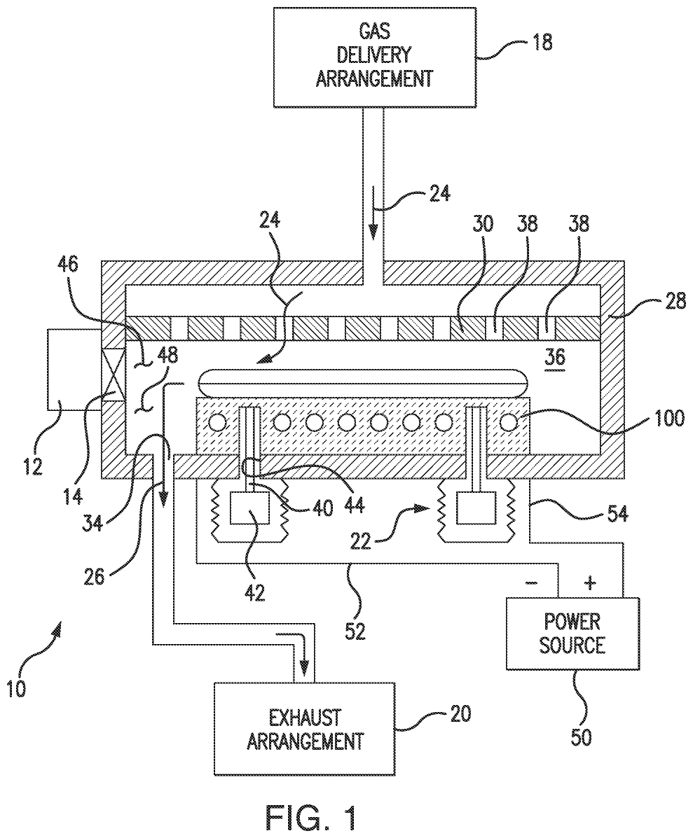

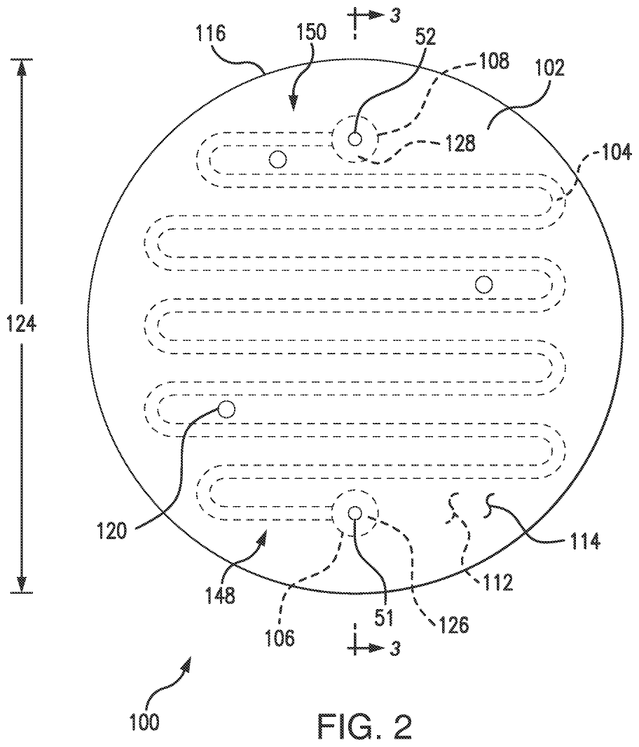

Reference will now be made to the drawings wherein like reference numerals identify similar structural features or aspects of the subject disclosure. For purposes of explanation and illustration, and not limitation, a partial view of an example of a substrate support in accordance with the present disclosure is shown in FIG. 1 and is designated generally by reference character 100. Other examples of substrate supports, semiconductor processing systems, and methods of making substrate supports for semiconductor processing systems in accordance with the present disclosure, or aspects thereof, are provided in FIGS. 2-12, as will be described. The systems and methods of the present disclosure may be used to support substrates in semiconductor processing systems during the fabrication of semiconductor devices, such as during the deposition of material layers onto substrates using chemical vapor deposition (CVD) or atomic layer deposition (ALD) techniques during the fabrication of integrated circuit semiconductor devices. However, it is to be understood and appreciated that the present disclosure is not limited to any CVD or ALD material layer deposition techniques or to the fabrication of any particular type of semiconductor device in general.

Referring to FIG. 1, a semiconductor processing system 10 including the substrate support 100 (e.g., a ceramic heater) is shown. The semiconductor processing system 10 includes a substrate transfer robot 12, a gate valve 14, and a reactor 16. The gate valve 14 couples the substrate transfer robot 12 to the reactor 16 and is configured to provide selective communication between the reactor 16 and the external environment. The substrate transfer robot 12 is supported for movement outside of the reactor 16 and is configured to transfer substrates, e.g., the substrate 2, into and out of the reactor 16. The reactor 16 houses the substrate support 100 is configured to deposit material layers, e.g., a material layer 4, onto substrates supported on the substrate support 100, for example, using a CVD or an ALD technique. As shown and described herein the reactor 16 includes a gas delivery arrangement 18, an exhaust arrangement 20, and a lift pin arrangement 22. As will be appreciated by those of skill in the art in view of the present disclosure, the semiconductor processing system 10 can include fewer or additional elements and remain within the scope of the present disclosure.

The gas delivery arrangement 18 is connected to the reactor 16 and is configured to provide a precursor 24 to the reactor 16. In certain examples the precursor 24 may include a silicon-containing precursor, such as silane or trichlorosilane by way of non-limiting example. In accordance with certain examples, the precursor 24 may include a metal-containing precursor such as trimethylaluminum by way of non-limiting example. It is also contemplated that, in accordance with certain examples, the gas delivery arrangement 18 may include a remote plasma unit. In such examples the remote plasma unit may be configured to generate a radical species, which the gas delivery arrangement 18 may in turn provide to the reactor 16 as the precursor 24.

The exhaust arrangement 20 is connected to the reactor 16, is coupled to the gas delivery arrangement 18 by the reactor 16, and is configured to receive a flow of exhaust 26 issued by the reactor 16. In certain examples, the exhaust 26 may include including residual precursor and/or reaction products issued by the reactor 16 during the deposition of the material layer 4 onto the substrate 2. In accordance with certain examples, the exhaust arrangement 20 may include a vacuum pump. In accordance with certain examples, the exhaust arrangement 20 may include an abatement devices, such as a scrubber by way of non-limiting example.

The reactor 16 includes a chamber body 28, a showerhead 30, and the substrate support 100. The chamber body 28 has an inlet port 32, an exhaust port 34, and an interior 36. The gas delivery arrangement 18 is connected to the inlet port 32 and is fluidly coupled therethrough to the interior 36 of the chamber body 28 to provide the precursor 24 therethrough to the interior 36 of the chamber body 28. The exhaust arrangement 20 is connected to the exhaust port 34 and is fluidly coupled therethrough the interior 36 of the chamber body 28 to receive the exhaust 26 issued by the chamber body 28. The showerhead 30 is seated within the interior 36 of the chamber body 28 between the inlet port 32 and the substrate support 100, has a plurality of flow apertures 38 extending therethrough, and fluidly couples the inlet port 32 to the substrate support 100 through the plurality of flow apertures 38. The substrate support 100 is seated within the interior 36 of the chamber body 28 between the showerhead 30 and the exhaust port 34, is formed from a ceramic material 110, and is configured to support the substrate 2 during deposition of the material layer 4 onto an upper surface 6 of the substrate 2.

The lift pin arrangement 22 includes a plurality of lift pins 40 and a lift pin actuator 42. The plurality of lift pins 40 configured for movement relative to the chamber body 28, disposed within lift pin apertures 44 extending through the chamber body 28, and are operably associated with the lift pin actuator 42. The lift pin actuator 42 is in turn configured to drive the plurality of lift pins 40 between an extended position 46 and a retracted position 48. When in the extended position 46, tips of the lift pins 40 are disposed above the substrate support 100 and within the interior 36 of the chamber body 28. When in the retracted position 48, tips of the lift pins 40 are disposed within substrate support 100. As will be appreciated by those of skill in the art in view of the present disclosure, moving the lift pins from extended position 46 to the retracted position 48 seats the substrate 2 on the substrate support 100 prior to heating the substrate 2 and depositing the material layer 4 onto the upper surface 6 of the substrate 2. As will also be appreciated by those of skill in the art in view of the present disclosure, moving the lift pins 40 from the retracted position 48 to the extended position 46 unseats the substrate 2 from the substrate support 100 subsequent to the deposition of the material layer 4 onto the upper surface 6 of the substrate 2.

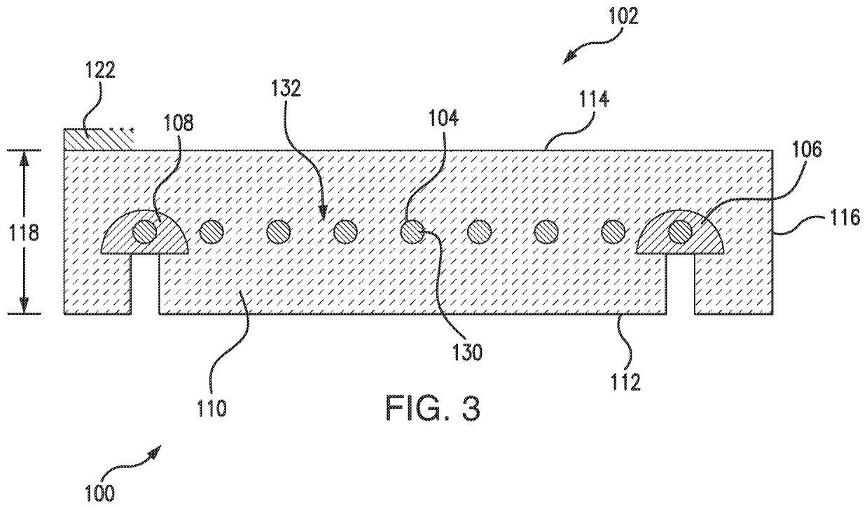

With reference to FIG. 2, the substrate support 100 is shown from in a bottom-up plan view. The substrate support 100 includes a heater body 102, a heater element 104, a first heater terminal 106, and a second heater terminal 108. The heater body 102 is formed from a ceramic material 110 (shown in FIG. 3) and has an upper surface 112, a lower surface 114, a periphery 116, and a thickness 118 (shown in FIG. 3). The upper surface 112 of the heater body 102 spans the periphery 116 of the heater body 102, overlays the lower surface 114 of the heater body 102, and is configured to support the substrate 2 (shown in FIG. 1) during the deposition of the material layer 4 (shown in FIG. 1) onto the upper surface 6 (shown in FIG. 1) of the substrate 2. The lower surface 114 of the heater body 102 is located on side of the heater body 102 opposite the upper surface 112 of the heater body 102, spans the periphery 116 of the heater body 102, and is spaced apart from the upper surface 112 by the thickness of the 118 of the heater body 102. It is contemplated that the lower surface 114 be separated from the showerhead 30 (shown in FIG. 1) by the upper surface 112 and the thickness 118 of the heater body 102 when the substrate support 100 is seated within the interior 36 (shown in FIG. 1) of the chamber body 28 (shown in FIG. 1).

The upper surface 112 and the lower surface 114 of the heater body 102 define a plurality of through-holes 120. Each of the through-holes 120 extend through the thickness 118 of the heater body 102 and couple the upper surface 112 of the heater body 102 to the lower surface 114 of the heater body 102. It is contemplated each of the through-holes 120 be registered to one of the plurality of lift pin apertures 44 (shown in FIG. 1) defined by the chamber body 28 (shown in FIG. 1). It is further contemplated that a respective one of the plurality of lift pins 40 (shown in FIG. 1) each be at least partially disposed within each of the plurality of through-holes 120. As shown and described herein the heater body 102 has three (3) through-holes 120. This is for illustration purposes only and is non-limiting. As will be appreciated by those of skill in the art in view of the present disclosure, the heater body 102 may have fewer than three (3) through-holes 120 or more than three (3) through-holes 120 and remain within the scope of the present disclosure.

The periphery 116 of the heater body 102 extends around the upper surface 112 and the lower surface 114 of the heater body 102 and couples the upper surface 112 to the lower surface 114 of the heater body 102. The periphery 116 of the heater body 102 further spans the thickness 118 (shown in FIG. 3) of the heater body 102 and defines a width 124 of the heater body 102. In certain examples, the thickness 118 may be between about 10 millimeters and about 50 millimeters. In accordance with certain examples, the thickness 118 may be between about 10 millimeters and about 40 millimeters. It is also contemplated that the thickness 118 may be between about 20 millimeter and about 30 millimeters. For example, the thickness 118 may be about 245 millimeters. Thicknesses within these ranges allow structures located within the thickness 118 of the heater body 102, e.g., the heater element 104, to communicate with the substrate 2 (shown in FIG. 1) while seated on the upper surface 112 of the heater body 102 through the heater body 102 while imparting robustness into the heater body 102. As will be appreciated by those of skill in the art in view of present disclosure, robustness in turn facilitates assembly of the heater body 102 within the chamber body 28 (shown in FIG. 1), for example, by resisting fracture during handling during the assembly process.

The width 124 spans the heater body 102 between laterally opposite sides of the heater body 102. In certain examples, the upper surface 112 and the lower surface 114 of the heater body 102 may be circular, the width 124 in such examples being a diameter of the upper surface 112 and the lower surface 114 of the heater body 102. In such examples the width 124 may be between about 100 millimeters and about 500 millimeters, or between about 150 millimeters and about 500 millimeters, or between about 200 millimeters and about 500 millimeters, or between about 300 millimeters and about 500 millimeters, or even between about 450 millimeters and about 500 millimeters. The width 124 may be about 325 millimeters. As will be appreciated by those of skill in the art in view of the present disclosure, diameters within these ranges allow the substrate support 100 (shown in FIG. 1) to support substrates including silicon wafers, such as 200-millimeter, 300-millimeter, or even 450-millimeter silicon wafers.

In accordance with certain examples, the heater body 102 may be polygonal in shape. For example, the upper surface 112 and the lower surface 114 of the heater body 102 may be square or rectangular in shape. As will be appreciated by those of skill in the art in view of the present disclosure, such polygonal shapes may facilitate the deposition of material layers onto the substrate 2 during the fabrication of semiconductor devices employed in solar and/or display applications. As will also be appreciated by those of skill in the art in view of the present disclosure, the periphery 116 may define another shape and remain within the scope of the present disclosure.

The heater element 104 is embedded within the ceramic material 110 and is configured to resistively heat the substrate 2 (shown in FIG. 1) while seated on the upper surface 112 of the heater body 102. In this respect the heater element 104 configured for electrical communication with the power supply 50 (shown in FIG. 1). It is contemplated that electrical communication between the heater element 104 and the power supply 50 be accomplished through the first heater terminal 106, the second heater terminal 108, the first lead 52, and the second lead 54. In this respect the first heater terminal 106 is connected to a first end 148 of the heater element 104, abuts the first lead 52, and is electrically coupled to the power supply 50 through the first lead 52. In further respect, the second heater terminal 108 is connected to second end 150 of the heater element 104, abuts the second lead 54, and is electrically coupled to the power supply 50 through the second lead 54. In the illustrated example the lower surface 114 of the heater body 102 defines therein a first recess 126 and a second recess 128. The first recess 126 is bounded in part by the first heater terminal 106 and the first lead 52 extends into the first recess 126 such that the first lead 52 abuts the first heater terminal 106. The second recess 128 is bounded in part the second heater terminal 108 and the second lead 54 extends into the second recess 128 such that the second lead 54 abuts the second heater terminal 108. As will be appreciated by those of skill in the art in view of the present disclosure, coupling the first lead 52 and the second lead 54 to the heater element 104 within the first recess 126 and the second recess 128 may simplify assembly of the substrate support 100 (shown in FIG. 1) within the interior 36 (shown in FIG. 1) of the chamber body 28 (shown in FIG. 1). As will also be appreciated by those of skill in the art in view of the present disclosure, other electrical communication arrangements are possible between the first heater terminal 106 and the second heater terminal 108 are possible and remain within the scope of the present disclosure.

With reference to FIG. 3, the heater body 102 is shown in a cross-sectional view. It is contemplated that the heater element 104 be formed from an electrically conductive material 130. In certain examples, the electrically conductive material 130 forming the heater element 104 may have a coefficient of thermal expansion substantially equivalent to a coefficient of thermal expansion of the ceramic material 110. For example, the heater element 104 may be formed from molybdenum or a molybdenum-containing alloy. Advantageously, forming the heater element 104 from an electrically conductive material having a coefficient of thermal expansion substantially equivalent to the coefficient of thermal expansion of the ceramic material 110 may limit stress exerted on the ceramic material 110 during heating of the substrate 2 (shown in FIG. 1). Limiting stress within the ceramic material 110 forming the heater body 102 reduces (or eliminates) the likelihood of crack formation within the heater body 102 during heating of the substrate 2, which may prolong the service of the substrate support 100 (shown in FIG. 1) in certain material layer deposition processes, such as in material layer deposition processes performed at high temperature and/or employing relatively high temperature ramp rate(s).

In certain examples, the heater element 104 may have a rounded cross-sectional profile 132. For example, the rounded cross-sectional profile 132 may have be arcuate, elliptical, or circular in shape, such as in examples where the heater element 104 is formed as a coil. Advantageously, forming the heater element 104 with the rounded cross-sectional profile 132 may limit stress exerted on the ceramic material 110 during heating of the substrate 2 by reducing (or eliminating) stress-concentrating features within the heater body 102, such as at joints where surfaces join one another at a 90-degree angle. Limiting stress within the ceramic material 110 forming the heater body 102 may also reduce (or eliminate) likelihood of crack formation within the heater body 102 during heating of the substrate 2 (shown in FIG. 1), potentially prolonging the service life of the substrate support 100 (shown in FIG. 1) in certain material layer deposition processes, such as in material layer deposition processes performed at high temperature and/or employing relatively high temperature ramp rate(s).

In certain examples, the ceramic material 110 may monolithically define the heater body 102. In this respect it is contemplated that the ceramic material 110 may extend contiguously between the upper surface 112 and the lower surface 114 of the heater body 102 through the thickness 118 of the heater body 102. In further respect, the ceramic material 110 may extend contiguously across the width 124 (shown in FIG. 2) of the heater body 102, for example, between laterally opposite sides of the periphery 116 of the heater body 102. It is also contemplated that the ceramic material 110 may extend contiguously between both the upper surface 112 and the lower surface 114 of the heater body 102 as well as between laterally opposite sides of the periphery 116 of the heater body 102.

In certain examples, the ceramic material 110 may define the upper surface 112 of the heater body 102. In accordance with certain example, the ceramic material 110 may define the lower surface 114 of the heater body 102. It is contemplated that, in certain examples, the ceramic material 110 may define the periphery 116 of the heater body 102. It is also contemplated that, in accordance with certain examples, a coating 122 may overlay the ceramic material 110 on one or more of the upper surface 112, the lower surface 114, and/or the periphery 116 of the heater body 102. As will be appreciated by those of skill in the art in view of the present disclosure, employment of a coating overlaying the bulk ceramic material forming the heater body 102 may impart a material characteristic to the heater body 102 (e.g., corrosion resistance) differing from that of the bulk ceramic material forming the heater body 102.

In certain examples, the ceramic material 110 may include alumina (Al₂O₃). In accordance with certain examples, the ceramic material 110 may include aluminum nitride (AlN). In accordance with certain examples, the ceramic material 110 may include silicon carbide (SiC). It is contemplated that the ceramic material 110 may include yttrium oxide (Y₂O₃). It is also contemplated that, in accordance with certain examples, the ceramic material 110 may include a ceramic composite comprising two or more ceramic materials, such as alumina and aluminum nitride by way of non-limiting example. For example, the ceramic material 110 may include YAG (3Y₂O₃·5Al₂O₃: yttrium aluminum garnet), YAM (2Y₂O₃·Al₂O₃: yttrium aluminum monoclinic), YAP (Y₂O₃·Al₂O₃: yttrium aluminum perovskite) by way of non-limiting example. As will be appreciated by those of skill in the art in view of the present disclosure, such ceramic materials may be suitably resistant to corrosion and/or tolerant of high temperatures, e.g., temperatures greater than about 250 degrees Celsius (° C.), or greater than about 350° C., or even greater than about 450° C., allowing for rapid deposition of the material layer 4 (shown in FIG. 1) onto the upper surface 6 (shown in FIG. 1) of the substrate 2 (shown in FIG. 1) while seated on the upper surface 112 of the heater body 102.

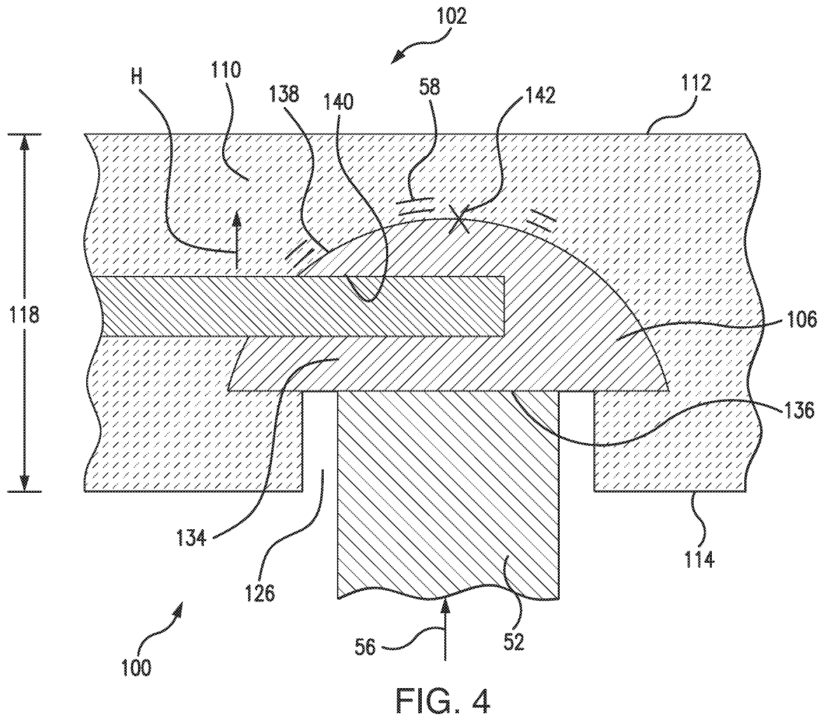

With reference to FIG. 4, a portion of the substrate support 100 including the first heater terminal 106 is shown. The first heater terminal 106 is formed from a heater terminal material 134, has an electrode surface 136 and a rounded surface 138, and defines a heater element socket 140. It is contemplated that the heater terminal material 134 be electrically conductive material. In certain examples the heater terminal material 134 may have a coefficient of thermal expansion that is substantially equivalent to a coefficient of thermal expansion of the ceramic material 110. In accordance with certain examples, the heater terminal material 134 may be formed from molybdenum or a molybdenum-containing alloy. It is also contemplated that, in accordance with certain examples, that the heater terminal material 134 and the heater element 104 may be formed from a common material. Advantageously, forming the first heater terminal 106 from a heater terminal material having a coefficient of thermal expansion substantially equivalent to the coefficient of thermal expansion of the ceramic material 110 may further limit stress 58 exerted on the ceramic material 110 during communication of heat H to the substrate 2. Limiting stress within the ceramic material 110 forming the heater body 102 in turn may reduce (or eliminate) likelihood of crack formation within the heater body 102 during heating of the substrate 2 (shown in FIG. 1), prolonging service life of the substrate support 100 in certain material layer deposition processes, such as in material layer deposition processes performed at high temperature and/or employing relatively high temperature ramp rate(s).

The electrode surface 136 opposes the lower surface 114 of the heater body 102, is spaced apart from the upper surface 112 of the heater body 102 by the rounded surface 138, and bounds (at least partially) a portion of the first recess 126. In this respect the first recess 126 is defined within the lower surface 114 of the heater body 102, extends partially through the thickness 118 of the heater body 102, and terminates at the electrode surface 136 of the first heater terminal 106. It is contemplated that the electrode surface 136 be arranged between the upper surface 112 and the lower surface 114 of the heater body 102, that the first lead 52 extend into the first recess 126, and that an end of the first lead 52 abut the electrode surface 136 such that the first lead 52 is in electrical communication with the first heater terminal 106 at the electrode surface 136. In certain examples, the electrode surface 136 may be partially exposed to the environment external to the heater body 102. In accordance with certain examples, the electrode surface 136 may be embedded within the ceramic material 110 forming the heater body 102. It is also contemplated that, in accordance with certain examples, the electrode surface 136 may be partially exposed to the environment external to the heater body 102 and partially embedded within the ceramic material forming the heater body 102.

The rounded surface 138 opposes the upper surface 112 of the heater body 102, defines a generally convex shape relative to the upper surface 112 of the heater body 102, and is embedded within the ceramic material 110 forming the heater body 102. It is contemplated that the rounded surface 138 be separated from the lower surface 114 of the heater body 102 by the electrode surface 136 of the first heater terminal 106, and that the rounded surface 138 of the first heater terminal 106 further spans the electrode surface 136 of the first heater terminal 106. Advantageously, forming the first heater terminal 106 with the rounded surface 138 limits (or eliminates) stress concentration features within the ceramic material 110, such as when surfaces of embedded structures join one another at 90-degree angles. Limiting (or eliminating) stress concentration features within the ceramic material 110 reduces stress exerted on the ceramic material 110 during heating of the substrate 2 (shown in FIG. 1) while seated on the substrate support 100 (shown in FIG. 1), reducing (or eliminating) likelihood of crack formation within the heater body 102 during heating of the substrate 2 (shown in FIG. 1) and potentially prolonging service life of the substrate support 100 in certain material layer deposition processes. In the illustrated example the rounded surface 138 defines a semicircular profile 144, the electrode surface 136 has a circular shape 146 (shown in FIG. 2), the first heater terminal 106 thereby being generally hemispherical in shape.

In the illustrated example the rounded surface 138 of the first heater terminal 106 joins the electrode surface 136 of the first heater terminal 106 at an acute angle 152. Without being bound by a particular theory, it is believed that locating the acute angle 152 below the heater element 104 limits the stress concentration otherwise associated with the acute angle 152 due to the relatively low level of heat flux below the heater element 104 relative to that above the heater element 104, allowing the acute angle 152 to be embedded within the ceramic material 110 to simplify fabrication of the first heater element 106.

The heater element socket 140 is defined between an apex 142 of the rounded surface 138 and the electrode surface 136, extends into an interior of the first heater terminal 106 from an opening defined in the rounded surface 138, and is configured to receive therein a first end 148 of the heater element 104. It is contemplated that the apex 142 of the rounded surface 138 be located within the thickness 118 of the heater body 102 between the upper surface 112 and the lower surface 114 of the heater body 102. It is further contemplated that the first end 148 of the heater element 104 is seated within the heater element socket 140, in electrical communication with the heater terminal material 134 through walls of the heater element socket 140, and is electrically coupled by the walls of the heater element socket 140 and the heater terminal material 134 with first lead 52 through the electrode surface 136 of the first heater terminal 106 such that the heater element 104 is electrically connected to the first heater terminal between the apex 142 of the first heater terminal 106 and the electrode surface 136 of the first heater terminal 106. In certain examples, the walls of the heater element socket 140 may be polished, which reduces resistance between the first heater terminal 106 and the heater element 104 during communication of an electric current 56 between the first lead 52 and the heater element 104.

The second heater terminal 108 (shown in FIG. 2) is similar to the first heater terminal 106, is spaced apart from the first heater terminal 106 by the heater element 104, and seats therein a second end 150 (shown in FIG. 2) of the heater element 104. As will be appreciated by those of skill in the art in view of the present disclosure, forming both first heater terminal 106 and the second heater terminal 108 with a hemispherical shape limits stress exerted on the ceramic material 110 within portions of the heater body 102 wherein the rounded surfaces of both the first heater terminal 106 and the second heater terminal 108 are embedded.

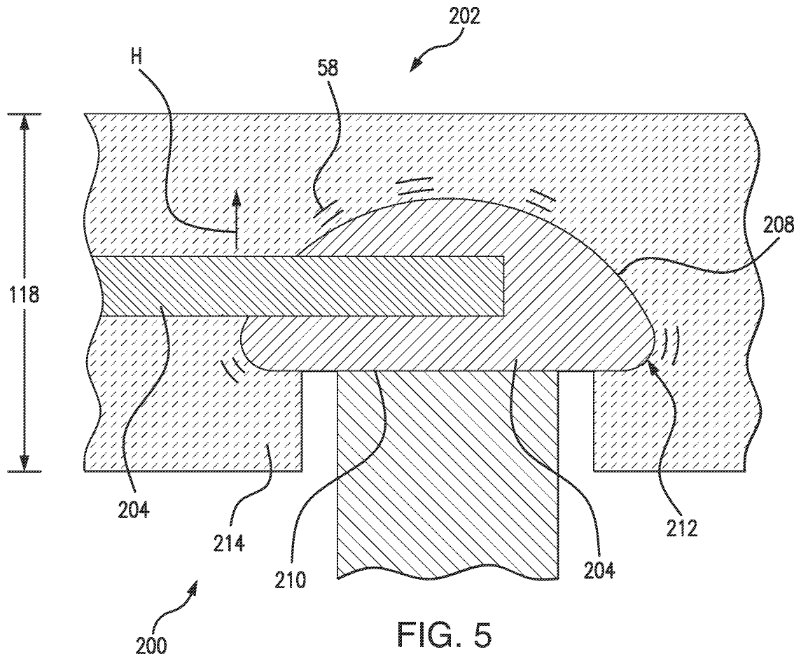

With reference to FIG. 5, a substrate support 200 is shown. The substrate support 200 is similar to the substrate support 100 (shown in FIG. 1) and additionally includes a heater body 202 including a heater element 204 and a first heater terminal 206. The first heater terminal 206 has a rounded surface 208 coupled to an electrode surface 210 by a filleted surface 212. It is contemplated that the filleted surface 212 extend circumferentially about the first heater terminal 206, the first heater terminal 206 thereby having no adjoining surfaces defining stress concentration features within a ceramic material 214 forming the heater body 202. As has been explained above, limiting (or eliminating) stress concentration features within the ceramic material forming the heater body 202 may limit stress 58 exerted on the ceramic material 214 during communication of heat H to the substrate 2 (shown in FIG. 2). Limiting stress may in turn reduce (or eliminate) likelihood of crack formation within the heater body 202 during heating of the substrate 2, potentially prolonging service life of the substrate support 200 in certain material layer deposition processes, such as in material layer deposition processes performed at high temperature and/or employing relatively high temperature ramp rate(s).

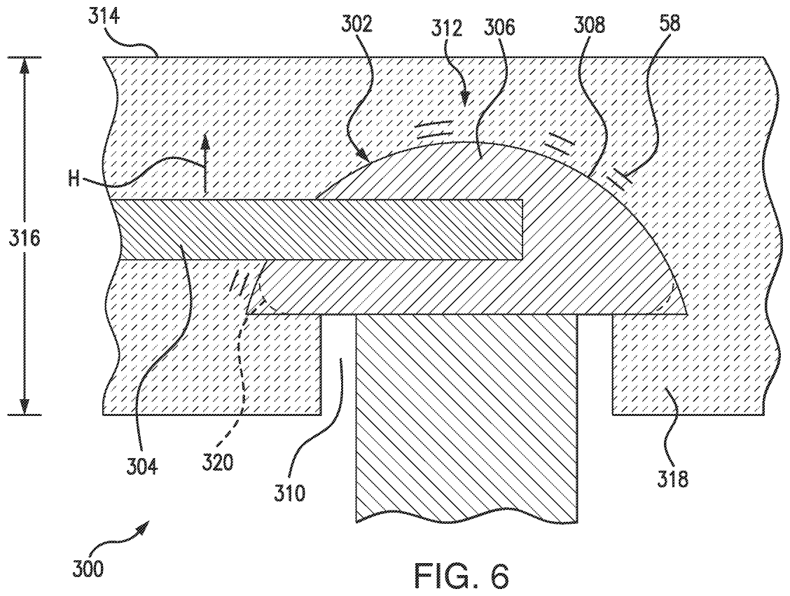

With reference to FIG. 6, a substrate support 300 is shown. The substrate support 300 is similar to the substrate support 100 (shown in FIG. 1) and additionally includes a heater body 302 with a heater element 304 and a first heater terminal 306. The first heater terminal 306 has a rounded surface 308 and an opposite electrode surface 310. It is contemplated that the rounded surface 308 define a substantially parabolic profile 312. In certain examples, the shape of the parabolic profile 312 corresponds to thermal gradient within the heater body 302 during communication of the heat H to the substrate 2 (shown in FIG. 1) while seated on an upper surface 314 of the heater body 302, e.g., by having a relatively large slope proximate the heater element 304 and a relatively small slope proximate the upper surface 314 of the heater body 302.

As will be appreciated by those of skill in the art in view of the present disclosure, the parabolic profile 312 may limit lateral force component a graduated within a thickness 316 of the heater body 302. Limiting lateral force component within the thickness 316 of the heater body 302 may in turn limit resistance to slippage at an interface between the rounded surface 308 and a ceramic material 318 forming the heater body 302. Limiting resistance to slippage may limit stress 58 exerted on the ceramic material 318 during communication of heat H to the substrate 2 (shown in FIG. 2). Limiting stress may in turn reduce (or eliminate) likelihood of crack formation within the heater body 302 during heating of the substrate 2, potentially prolonging service life of the substrate support 300 in certain material layer deposition processes, such as in material layer deposition processes performed at high temperature and/or employing relatively high temperature ramp rate(s). In certain examples, the first heater terminal 206 may have a filleted surface 320 coupling (e.g., defined between) the rounded surface 308 to the electrode surface 310 of the first heater terminal 306.

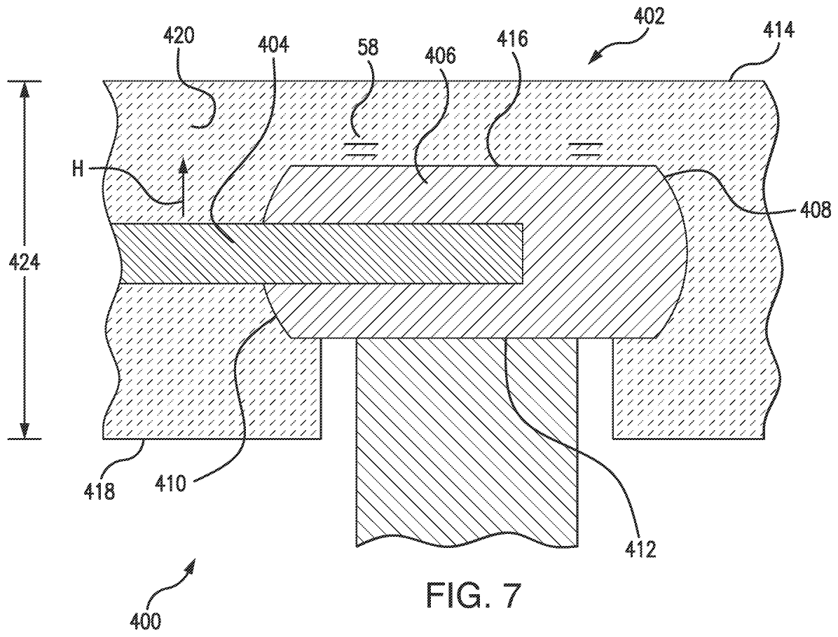

With reference to FIG. 7, a substrate support 400 is shown. The substrate support 400 is similar to the substrate support 100 (shown in FIG. 1) and additionally includes a heater body 402, a heater element 404, and a first heater terminal 406. The first heater terminal 406 has a first rounded surface 408, a second rounded surface 410, and an electrode surface 412. The first rounded surface 408 opposes an upper surface 414 of the heater body 402 and extends about an upper planar surface 416 of the first heater terminal 406. The second rounded surface 410 opposes a lower surface 418 of the heater body 402, is separated from the first rounded surface 408 by the heater element 404, and extends about the electrode surface 412 of the first heater terminal 406. As will be appreciated by those of skill in the art in view of the present disclosure, forming the first heater terminal 406 with a first rounded surface 408 and a second rounded surface 410 may simplify fabrication of the substrate support 400 as the reduction in stress 58 exerted on a ceramic material 420 associated with avoiding 90-degrees edges on the first heater terminal 406 during the communication of heat H is realized irrespective of the orientation of the first heater terminal 406, error-proofing fabrication of the substrate support 400 with respect to orientation of the first heater terminal 406 within a thickness 424 of the heater body 402.

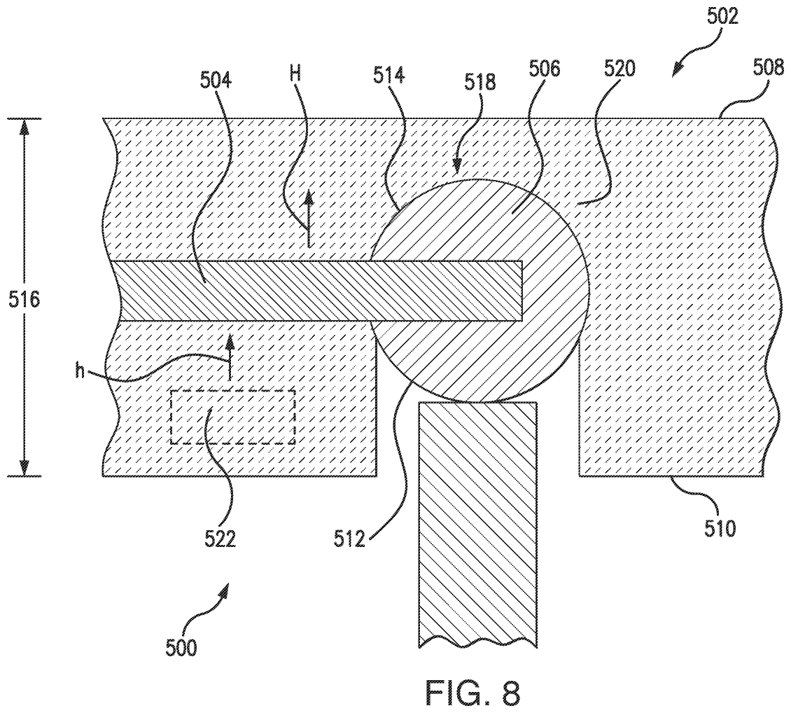

With reference to FIG. 8, a substrate support 500 is shown. The substrate support 500 is similar to the substrate support 100 (shown in FIG. 1) and additionally includes a heater body 502, a heater element 504, and a first heater terminal 506. The heater element 504 is arranged within the heater body 502 between an upper surface 508 and a lower surface 510 of the heater body 502 and is electrically connected to the first heater terminal 506. The first heater terminal 506 has an electrode surface 512 opposing the lower surface 510 of the heater body 502 and a rounded surface 514 opposing the upper surface 508 of the heater body 502. In the illustrated example the rounded surface 514 of the first heater terminal 506 and the electrode surface 512 of the first heater terminal 506 collectively form a circular shape within a thickness 516 of the heater body 502, the first heater terminal 506 thereby defining a circular profile 518 within the thickness 516 of the heater body 502, the first heater terminal 506 thereby being generally spherical in shape. As will be appreciated by those of skill in the art in view of the present disclosure, forming the first heater terminal 506 such the first heater terminal 506 defines a circular profile may limit stress exerted on a ceramic material 520 forming the heater body 502 in examples where thermal gradient may change within the thickness 516 of the heater body 502 independent of heat H communicated by the heater element 504, for example, when the heater element 504 is a first heater element 504 and the substrate support 500 includes a second heater element 522 arranged between the first heater element 504 and the lower surface 510 of the heater body 502 generating heat h independently of the heat H communicated by the first heater element 504.

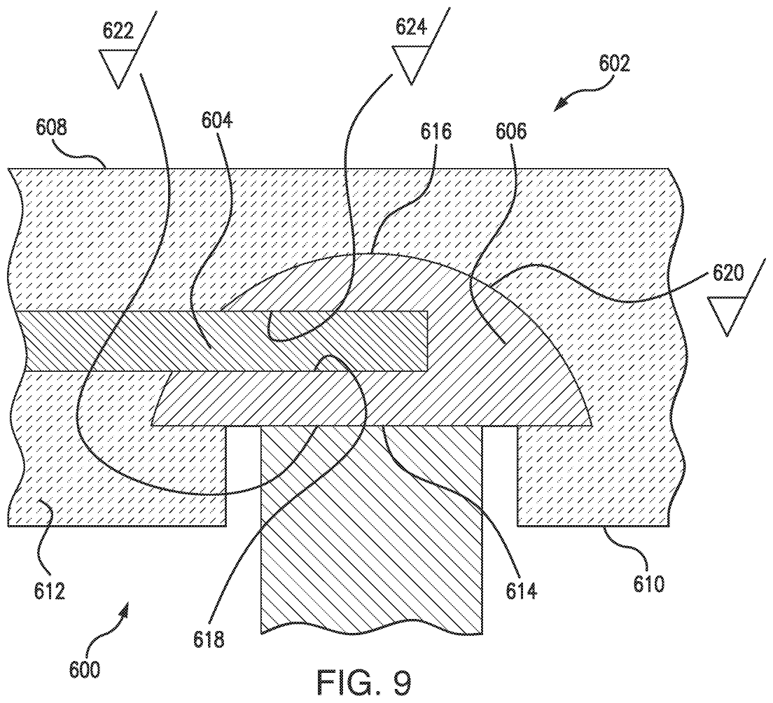

With reference to FIG. 9, a substrate support 600 is shown. The substrate support 600 is similar to the substrate support 100 (shown in FIG. 1) and includes a heater body 602, a heater element 604, and a first heater terminal 606. The heater element 604 is arranged between an upper surface 608 and a lower surface 610 of heater body 602, is embedded within a ceramic material 612 forming the heater body 602, and is electrically connected to the first heater terminal 606. The first heater terminal 606 has an electrode surface 614 opposing the lower surface 610 of the heater body 602, a rounded surface 616 opposing the upper surface 608 of the heater body 602, and defines a heater element socket 618 within an interior of the first heater terminal 606. The rounded surface 616 has a rounded surface roughness 620, the electrode surface 614 has an electrode surface roughness 622, and the rounded surface roughness 620 is less than the electrode surface roughness 622. Advantageously, limiting roughness of the rounded surface 616 can limit stress within the ceramic material 612 forming the heater body 602. As will be appreciated by those of skill in the art in view of the present disclosure, limiting stress within the ceramic material 612 forming the heater body 602 may reduce (or eliminate) cracking during communication of the heat H to the upper surface 608 of the heater body 602 by the heater element 604, potentially prolonging service life of the substrate support 600 in certain material layer deposition processes, such as in material layer deposition processes performed at high temperature and/or employing relatively high temperature ramp rate(s).

In certain examples, the rounded surface 616 of the first heater terminal 606 may be polished, such as to a mirror polish surface roughness. In such examples the electrode surface 614 may be unpolished or less polished than the rounded surface 616 of the first heater terminal 606. In accordance with certain examples, the rounded surface 616 of the first heater terminal 606 may be honed, such as to a honed surface roughness. In such examples the electrode surface 614 of the first heater terminal 606 may be unhoned or less honed than the rounded surface 616 of the first heater terminal 606. It is contemplated that the rounded surface roughness 620 may be between about 1000 angstroms and about 100 angstroms, or between about 500 angstroms and about 100 angstroms, or even between about 200 angstroms and about 100 angstroms. Without being bound by a particular theory or mode of operation, it is believed that rounded surface roughness within these ranges limit stress by generating a thin film of ceramic particulate between the first heater terminal 606 the ceramic material 612 forming the heater body 602, the ceramic particular functioning as a lubricant between the first heater terminal 606 and the ceramic material 612 during intervals during which the rate of thermal expansion of the first heater terminal 606 is mismatched with respect the rate of thermal expansion of the ceramic material 612.

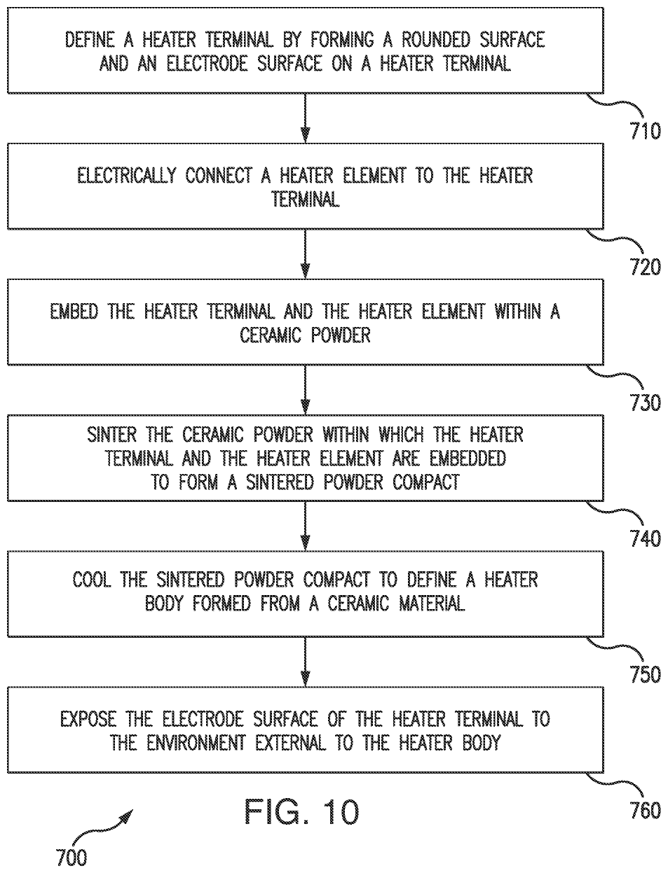

With reference to FIGS. 10-12, a method 700 of making a substrate support for a semiconductor processing system, e.g., the substrate support 100 (shown in FIG. 1) for the semiconductor processing system 10 (shown in FIG. 1), is shown according to an illustrative example of the method. As shown in FIG. 10, the method 700 starts by defining a heater terminal by forming a rounded surface and an electrode surface on the heater terminal, e.g., the first heater terminal 106 (shown in FIG. 2) with the rounded surface 138 (shown in FIG. 3) and the electrode surface 136 (shown in FIG. 3), as shown with box 710. Next, the heater terminal is electrically connected to a heater element, e.g., the heater element 104 (shown n in FIG. 2), as shown with box 720. The heater terminal and the heater element are then embedded within a ceramic powder and the powder compacted to form powder compact, as shown with box 730. The powder compact is sintered, and the sintered powder compact thereafter cooled to define a heater body formed from a ceramic material, e.g., the heater body 102 (shown in FIG. 2) formed from the ceramic material 110, as shown with box 740 and box 750.

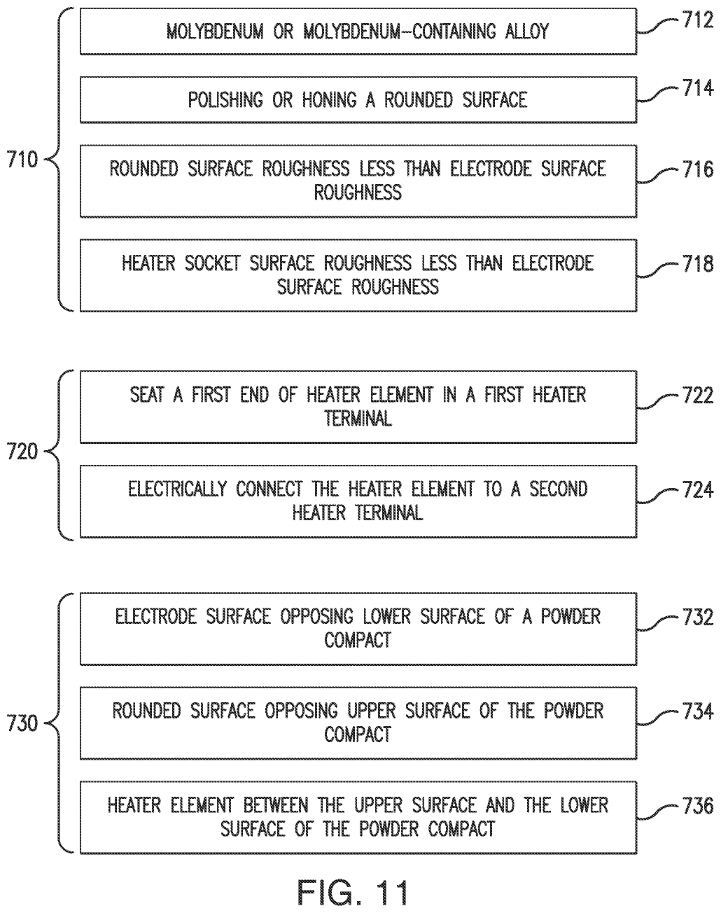

As shown in FIG. 11, defining 710 the heater terminal may include forming the heater body from molybdenum or a molybdenum-containing alloy, as shown with box 712. Defining the heater terminal may include polishing or honing the rounded surface of the heater terminal, as shown with box 714. Defining the heater terminal may include polishing or honing the rounded surface such that a rounded surface roughness, e.g., the rounded surface roughness 620 (shown in FIG. 9), of the rounded surface is less than an electrode surface roughness, e.g., the electrode surface roughness 622 (shown in FIG. 9), of the electrode surface, as shown with box 716. Defining the heater terminal may include polishing or honing a heater seat surface such that a heater socket surface roughness located within the heater terminal, e.g., the heater seat surface roughness 624 (shown in FIG. 9), and the rounded surface roughness are less than the electrode surface roughness, as shown with box m718.

Electrically connecting 720 the heater element to the heater terminal may include seating an end of the heater element into a heater element socket, e.g., the first end 148 (shown in FIG. 2) of the heater element 104 (shown in FIG. 2) into the heater element socket 140, as shown with box 722. Once the heater element is connected to the heater terminal, an opposite second end of the heater element may be electrically connected to a second heater terminal, e.g., the second end 150 (shown in FIG. 2) electrically connected to the second heater terminal 108 (shown in FIG. 2), as shown with box 724.

Embedding 730 the heater element and the heater terminal within the ceramic powder may include arranging the heater terminal within the ceramic powder such that the electrode surface of the heater terminal opposes a lower surface of the powder compact, as shown with box 732. Embedding 730 the heater element and the heater terminal within the ceramic powder may also include arranging the heater terminal within the ceramic powder such the rounded surface of the heater terminal opposes an upper surface of the powder compact, as shown with box 734. Embedding 730 the heater element and the heater terminal within the ceramic powder may further include arranging heater element within the ceramic powder between the upper surface and the lower surface of the powder compact, as show with box 736.

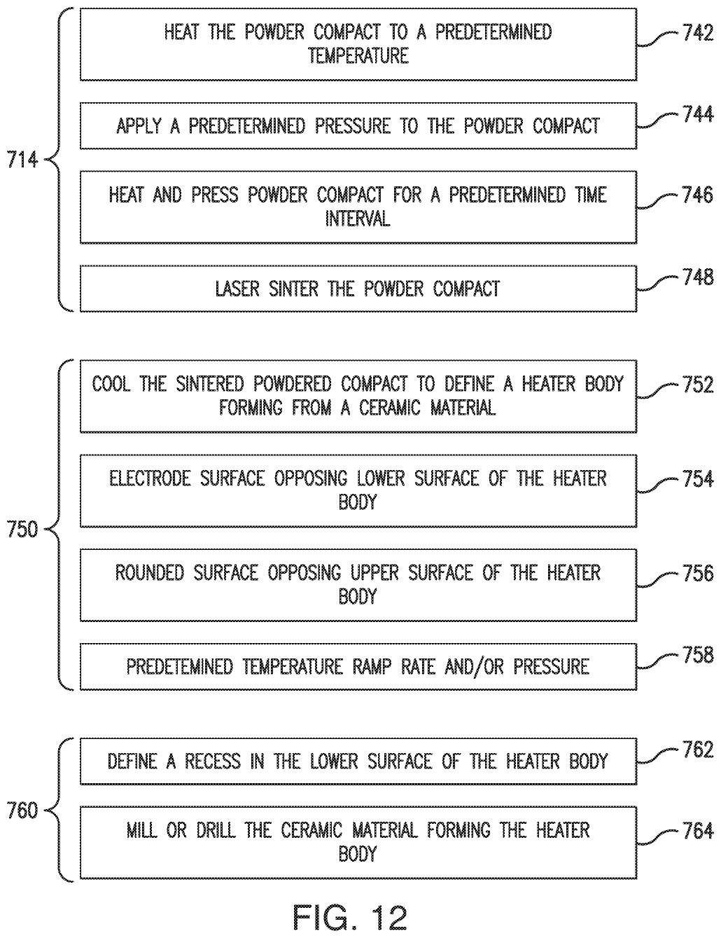

As shown in FIG. 12, sintering 740 the ceramic powder may include heating the ceramic powder to a predetermined temperature, as shown with box 742. Sintering 740 the ceramic powder may include heating the ceramic powder under a predetermined pressure, as shown with box 744. Sintering 740 the ceramic powder may include heating and/or applying pressure to the ceramic powder for a predetermined time interval, as shown with box 746. Sintering may be accomplished using a laser sintering technique, as shown with box 748.

Cooling 750 the sintered powder compact may include cooling the sintered powder compact to homogenously form the heater body from a ceramic material, e.g., the ceramic material 110 (shown in FIG. 3), as shown with box 752. Cooling 750 the sintered powder compact may also include cooling the sintered powder compact such that the heater element and the heater terminal are arranged between the upper surface and the lower surface of the heater body, e.g., between the upper surface 112 (shown in FIG. 2) and the lower surface 114 (shown in FIG. 2) of the heater body 102, as shown with box 754. Cooling 750 the sintered powder compact include cooling the sintered powder compact such that the rounded surface opposes the upper surface of the heater body and is embedded within the ceramic material forming the heater body to limit stress within the ceramic material during heating of a substrate seated on the upper surface of the heater body, as shown with box 756. The sintered powder compact may be cooled at one or more of a predetermined temperature ramp rate and/or pressure to define a predetermined ceramic composition (or ceramic composite of two or more ceramic materials), as shown with box 758.

As shown with box 760, the electrode surface of the heater terminal is thereafter at least partially exposed to the environment external of the heater body. Exposing 760 the electrode surface of the heater terminal may include defining a recess in the lower surface of the heater body, e.g., the first recess 126 (shown in FIG. 3), as shown with box 762. Exposing 760 the electrode surface of the heater terminal may include milling or drilling the ceramic material forming the heater body to expose the electrode surface of the heater terminal, as shown with box 764.

The description of exemplary embodiments provided above is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

As used herein, a “substrate” refers to any material having a surface onto which material can be deposited. A substrate may include a bulk material such as silicon (e.g., single crystal silicon) or may include one or more layers overlaying the bulk material. Further, the substrate may include various topologies, such as trenches, vias, lines, and the like formed within or on at least a portion of a layer of the substrate.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate support, comprising:
a heater body formed from a ceramic material with an upper surface and a lower surface separated by a thickness of the heater body;
a heater element arranged between the upper surface and the lower surface of the heater body, the heater element embedded within the ceramic material forming the heater body;
a heater terminal arranged between the upper surface and the lower surface of the heater body, the heater terminal electrically connected to the heater element; and
wherein the terminal has an electrode surface and a rounded surface, the electrode surface opposing the lower surface of the heater body to flow an electric current to the heater element, the rounded surface opposing the upper surface of the heater body and embedded within the ceramic material to limit stress in the ceramic material during heating of a substrate seated on the upper surface of the heater body.

2. The substrate support of claim 1, wherein the rounded surface of the heater terminal spans the electrode surface of the heater terminal, wherein the rounded surface has a semicircular profile with a convex shape relative to the upper surface of the heater body.

3. The substrate support of claim 1, wherein the rounded surface has an apex, and wherein the heater element is electrically connected to the heater terminal between the apex and the electrode surface of the heater terminal.

4. The substrate support of claim 1, wherein the heater terminal comprises molybdenum.

5. The substrate support of claim 1, wherein the rounded surface has a rounded surface roughness, wherein the electrode surface has an electrode surface roughness, and wherein the rounded surface roughness is less than the electrode surface roughness.

6. The substrate support of claim 1, wherein the rounded surface of the heater terminal has a rounded surface roughness that is between about 1000 angstroms and about 100 angstroms, between about 500 angstroms and about 100 angstroms, or between about 200 angstroms and about 100 angstroms.

7. The substrate support of claim 1, wherein the rounded surface of the heater terminal defines (a) a semicircular profile, (b) a parabolic profile, or a (c) a circular profile.

8. The substrate support of claim 1, wherein the ceramic material extends contiguously between the upper surface and the lower surface of the heater body.

9. The substrate support of claim 1, wherein the ceramic material extends contiguously between laterally opposite sides of the heater body.

10. The substrate support of claim 1, wherein the ceramic material includes alumina, aluminum nitride, silicon carbide, yttrium oxide, or a ceramic composite.

11. The substrate support of claim 1, wherein the lower surface of the heater body defines a recess, and wherein the electrode surface at least partially bounds the recess.

12. The substrate support of claim 1, wherein the electrode surface of the heater terminal is at least partially embedded within the ceramic material forming the heater body.

13. The substrate support of claim 1, wherein the electrode surface of the heater terminal is at least partially exposed an environment external to the heater body.

14. The substrate support of claim 1, wherein the upper surface and the lower surface of the heater body define a (a) disc-like shape, (b), a polygonal shape, (c) a square shape, or (d) a rectangular shape.

15. The substrate support of claim 1, wherein the rounded surface of the heater terminal joins the electrode surface of the heater terminal at an acute angle.

16. The substrate support of claim 1, wherein the rounded surface of the heater terminal joins the electrode surface of the heater terminal at a filleted surface.

17. The substrate support of claim 1, wherein the rounded surface is a first rounded surface and the heater terminal has a second rounded surface, the first rounded surface separating the second rounded surface from the upper surface of the heater body.

18. The substrate support of claim 1, wherein the rounded surface and the electrode surface of the heater terminal define a contiguous circular profile between the upper surface and the lower surface of the heater body.

19. A semiconductor processing system, comprising:
a gate valve;
a substrate transfer robot supported for movement relative to the gate valve;
a chamber body connected to the gate valve;
a substrate support as recited in claim 1 arranged within an interior of the chamber body, wherein the ceramic material forming the heater body includes aluminum nitride, wherein the upper surface and the lower surface define a disc-like shape, and wherein the rounded surface has a semicircular profile with a convex shape relative to the upper surface of the heater body.

20. A method making a substrate support, comprising:
defining a heater terminal with a rounded surface and an electrode surface;
electrically connecting a heater element to the heater terminal;
embedding the heater element and the heater terminal within a ceramic powder;
sintering the ceramic powder to form a sintered powder compact;
cooling the sintered powder compact to form a heater body formed from a ceramic material and having an upper surface and a lower surface;
whereby the heater element and the heater terminal are arranged between the upper surface and the lower surface of the heater body;
whereby the electrode surface opposes the lower surface of the heater body to flow an electric current to the heater element; and
whereby the rounded surface opposes the upper surface of the heater body and is embedded within the ceramic material to limit stress within the ceramic material during heating of a substrate seated on the upper surface of the heater body.
